(19) United States
(12) Patent Application Publication
(10) Pub. No.: US 2024/0224460 A1
(43) Pub. Date: Jul. 4, 2024

(54) POWER DISTRIBUTION UNIT AND RACK SYSTEM

(71) Applicant: BITMAIN TECHNOLOGIES INC., Beijing (CN)

(72) Inventors: Shaoming HUANG, Beijing (CN); Hongbo ZENG, Beijing (CN); Mingliang HAO, Beijing (CN); Hangkong HU, Beijing (CN); Yurong PENG, Beijing (CN); Zhihao ZHU, Beijing (CN)

(21) Appl. No.: 18/604,242

(22) Filed: Mar. 13, 2024

Related U.S. Application Data
(63) Continuation of application No. PCT/CN2022/113429, filed on Aug. 18, 2022.

(30) Foreign Application Priority Data
Sep. 14, 2021 (CN) 202122216947.4

(51) Int. Cl. H05K 7/14

(52) U.S. Cl. CPC H05K 7/1492

(57) ABSTRACT

Provided are a power distribution unit and a rack system. The power distribution unit includes: a terminal block (1) having an input terminal (11) for power supply and a lead-out terminal (12) for power supply; at least one wiring pad (2) respectively electrically connected to the lead-out terminal (12); a plurality of power output terminal groups (3), each power output terminal group (3) being composed of at least one power output terminal (31), and each power output terminal (31) being electrically connected to a respective wiring pad (2); and a plurality of switch mechanisms (4) provided in such a way that a switch mechanism (4) is correspondingly provided for a power output terminal group (3), where the switch mechanism (4) causes the corresponding power output terminal group (3) to be electrically connected to or electrically disconnected from the corresponding wiring pad (2).

### CROSS-REFERENCE TO RELATED APPLICATIONS

This application is a continuation of International Application No. PCT/CN2022/113429, filed on Aug. 18, 2022, which claims priority to Chinese Patent Application No. 202122216947.4, filed on Sep. 14, 2021 and entitled “POWER DISTRIBUTION UNIT AND RACK SYSTEM”, both of which are hereby incorporated by reference in their entireties.

### TECHNICAL FIELD

The present disclosure relates to, but is not limited to, the technical field of power supply, and in particular, to a power distribution unit and a rack system.

### BACKGROUND

A PDU (Power Distribution Unit) is a power distributor socket suitable for being mounted on, for example, a cabinet. The PDU has functions of power distribution and management, and provides power for an electronic device such as a cabinet, a server, and a data center.

However, the current PDU usually controls power output of all sockets by means of one switch. This cannot meet user requirements for cutting off some power supplies, and reduces the user experience. In addition, there are some shortcomings such as long and complicated internal routing of the PDU, which is not conducive to the miniaturization of the PDU.

### SUMMARY

The present disclosure provides a power distribution unit and a rack system.

In a first aspect according to an embodiment of the present disclosure, a power distribution unit is provided, including:
a terminal block having an input terminal for power supply and a lead-out terminal for power supply;
at least one wiring pad respectively electrically connected to the lead-out terminal;
a plurality of power output terminal groups, each power output terminal group being composed of at least one power output terminal, and each power output terminal being electrically connected to a respective wiring pad; and
a plurality of switch mechanisms provided in such a way that a switch mechanism is correspondingly provided for a power output terminal group, where the switch mechanism causes the corresponding power output terminal group to be electrically connected to or electrically disconnected from the corresponding wiring pad.

In an embodiment, one switch mechanism is correspondingly provided for one power output terminal group, and each power output terminal group is composed of two power output terminals.

In an embodiment, the plurality of power output terminal groups form at least two power output units, and the respective power output units are provided spaced apart from each other.

In an embodiment, the power output units are arranged along a first direction, and the switch mechanisms are each configured at a position adjacent to a corresponding power output unit, and are arranged along the first direction.

In an embodiment, when a power output unit is composed of a plurality of power output terminal groups, a plurality of switch mechanisms corresponding to the power output unit are arranged along a second direction perpendicular to the first direction.

In an embodiment, the switch mechanism includes a fixing groove for mounting the switch mechanism, and the fixing groove is fitted with a fixed guide rail provided at a housing of the power distribution unit.

In an embodiment, the fixing groove is a dovetail groove.

In an embodiment, the switch mechanism includes a special-shaped hole for allowing a cable to pass through and fixing the cable and a switch lever for operation; and the power output terminal includes a socket.

In an embodiment, a plurality of wiring pads are provided, and the respective wiring pads are connected independently of each other to the terminal block.

In an embodiment, the power distribution unit further includes a housing, where the housing has: a first side wall and a second side wall extending along a first direction and opposite to each other; a first end wall and a second end wall which are provided at two ends of the side walls in the first direction; and a top wall and a bottom wall which are opposite to each other and cover a space enclosed by the first side wall, the second side wall, the first end wall and the second end wall, where at least part of the switch mechanism and at least part of the power output terminal are exposed at the first side wall.

In an embodiment, a switch lever of the switch mechanism that is for operation, a cable of the power output terminal, and a socket connected to an end of the cable are exposed at the first side wall; and/or the switch lever of the switch mechanism that is for operation and the socket of the power output terminal are exposed at the first side wall.

In an embodiment, an input incoming mechanism is provided at the first end wall, the input incoming mechanism is electrically connected to the input terminal of the terminal block, and the terminal block is located inside the housing at a position close to the first end wall.

In an embodiment, the input incoming mechanism includes: a first hub ring provided on a side of the first end wall outside the housing; and a second hub ring provided on a side of the first end wall inside the housing, where the first hub ring is provided with a mounting groove in a surrounding manner, the first end wall of the housing is provided with a through hole for a cable to pass through, and the mounting groove is in communication with the through hole and is connected to the second hub ring.

In an embodiment, the input incoming mechanism further includes: a locking mechanism mounted to the bottom wall, where the locking mechanism and the bottom wall form a routing channel, and the cable is fixed inside the routing channel.

In an embodiment, at least one fixed guide rail is provided in the housing, the fixed guide rail is mounted to the bottom wall, the fixed guide rail includes an upright wall which is upright relative to the bottom wall in a mounted state, and the upright wall is capable of being snap-fitted with the fixing groove provided in the switch mechanism.

In an embodiment, the second end wall is provided with a socket.

In an embodiment, the power distribution unit further includes: a first mounting bracket provided outside the first end wall and connected to the first end wall, the first mounting bracket being provided with a mounting through-hole; and a second mounting bracket provided outside the second end wall and connected to the second end wall, the second mounting bracket being provided with a mounting through-hole.

In a second aspect according to an embodiment of the present disclosure, a rack system is provided, including: a rack and a power distribution unit according to any one of the above embodiments in the first aspect, where the rack includes a plurality of parallel laminates provided spaced apart from each other, and the power distribution unit is fixed to a side surface of a laminate.

The power distribution unit according to the embodiments of the present disclosure includes the terminal block, the at least one wiring pad, the plurality of power output terminal groups, and the plurality of switch mechanisms, where each power output terminal group is composed of at least one power output terminal, and each power output terminal is electrically connected to a respective wiring pad, thus avoiding direct output of the socket and reducing the size of the power distribution unit. The plurality of switch mechanisms are provided in such a way that a switch mechanism is correspondingly provided for a power output terminal group, and the switch mechanism causes a corresponding power output terminal group to be electrically connected to or electrically disconnected from the corresponding wiring pad, thereby achieving independent control of each power output terminal group, meeting user requirements, and improving the user experience.

In addition, the power output terminal groups are arranged along the first direction, and the switch mechanisms are each configured at a position adjacent to a corresponding power output terminal group, and are arranged in the first direction and/or the second direction perpendicular to the first direction. Therefore, an internal structural layout of the power distribution unit can be optimized by means of a reasonable layout of the power output terminals and the switch mechanisms, and miniaturization of the power distribution unit can be achieved.

It should be understood that the above general description and the following detailed description are merely exemplary and illustrative, and should not limit the present disclosure.

### BRIEF DESCRIPTION OF THE DRAWINGS

The accompanying drawings herein are incorporated into and constitute a part of the description, illustrate embodiments consistent with the present disclosure, and are used together with the description to explain the principles of the embodiments of the present disclosure.

FIG. 1 is a schematic structural diagram of a power distribution unit shown according to an exemplary embodiment.

FIG. 2 is a schematic diagram of an external structure of a power distribution unit shown according to an exemplary embodiment.

FIG. 3 is a schematic structural diagram of a switch mechanism shown according to an exemplary embodiment.

FIG. 4 is a schematic structural diagram of a fixing groove of a switch mechanism shown according to an exemplary embodiment.

FIG. 5 is a schematic diagram of an internal local structure of a power distribution unit shown according to an exemplary embodiment.

FIG. 6 is a schematic structural diagram of an input incoming mechanism shown according to an exemplary embodiment.

FIG. 7 is a schematic structural diagram of an input incoming mechanism and a locking mechanism shown according to an exemplary embodiment.

FIG. 8 is a schematic structural diagram of a power distribution unit shown according to another exemplary embodiment.

### DESCRIPTION OF REFERENCE SIGNS

1—Terminal block; 11—Input terminal; 12—Lead-out terminal; 2—Wiring pad; 3—Power output terminal group;
31—Power output terminal; 4—Switch mechanism; 41—Fixing groove; 42—Special-shaped hole; 43—Switch lever;
5—Housing; 51—First side wall; 52—Second side wall; 53—First end wall; 54—Second end wall; 55—Fixed guide rail;
6—Input incoming mechanism; 61—First hub ring; 62—Second hub ring; 63—Locking mechanism;
7—First mounting bracket; 8—Second mounting bracket.

### DESCRIPTION OF EMBODIMENTS

Exemplary embodiments will be described in detail herein, with examples shown in the accompanying drawings. Unless otherwise indicated, the same numbers in different accompanying drawings represent the same or similar elements when the following description refers to the accompanying drawings. Implementations described in the following exemplary embodiments do not represent all implementations consistent with the embodiments of the present disclosure. Instead, the implementations are merely examples of apparatuses and methods consistent with some aspects of the embodiments of the present disclosure as detailed in the appended claims.

In addition, the term indicating a direction and orientation in this description, such as “up”, “down”, “length”, “width” or “height”, is intended to explain a relative positional relationship of each component, and is not intended to limit the orientation and arrangement position of each component.

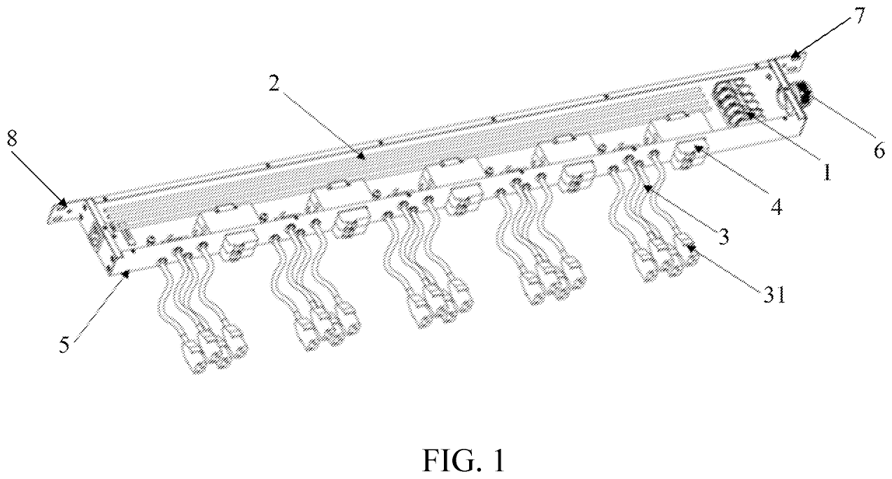

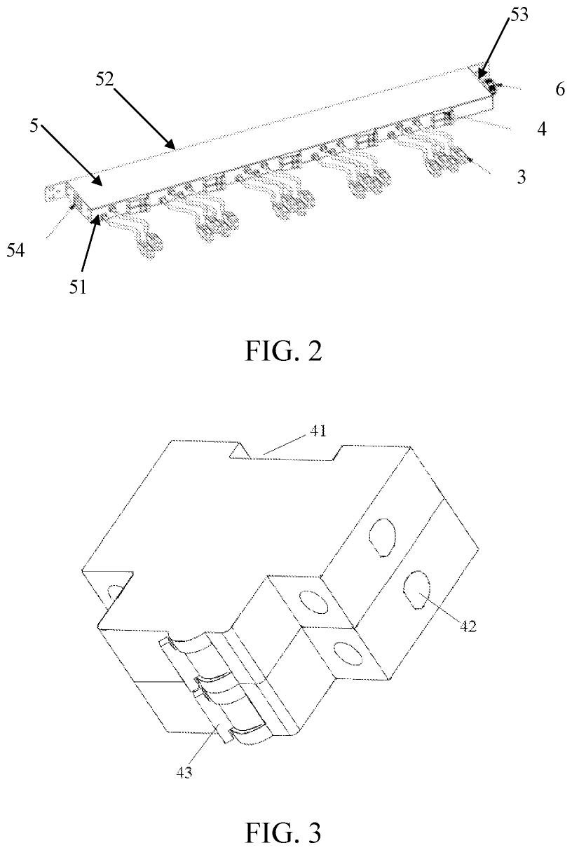

FIG. 1 and FIG. 2 schematically show an internal structure and an external structure of a power distribution unit according to an embodiment.

The power distribution unit may be used in devices such as a cabinet, a high-power server, and a data center. As shown in FIG. 1 and FIG. 2, the power distribution unit is elongated as a whole. In this description, a length direction of the power distribution unit is referred to as a first direction, a thickness direction (height direction) thereof is referred to as a second direction, and a width direction thereof is referred to as a third direction. As shown in FIG. 1, the power distribution unit includes: a terminal block 1, at least one wiring pad 2, a plurality of power output terminal groups 3, and a plurality of switch mechanisms 4. These components are received in a housing 5.

In an embodiment, as shown in FIG. 1 and FIG. 5, the terminal block 1 is provided inside the housing 5 of the power distribution unit at a position close to an end in the first direction. The terminal block 1 includes an input terminal 11 for power supply and a lead-out terminal 12 for power supply. The input terminal 11 is connected to an external power supply line, and the lead-out terminal 12 is connected to each wiring pad 2. In a case where a plurality of power supply lines or a plurality of wiring pads 2 are included, the power supply lines may be respectively connected to incoming terminals of the input terminal 11, and the wiring pads 2 may be respectively connected to outgoing terminals of the lead-out terminal 12.

As shown in FIG. 1, the plurality of wiring pads 2 extend in the first direction, for example, and are fixed inside the housing 5 in parallel with each other. The wiring pads 2 are provided independently of each other. The wiring pads 2 may have the same shape, extended length, etc., or may have different shapes, extended lengths, etc. The wiring pads 2 may have the same or different power. In this embodiment, the wiring pad 2 is a copper wiring pad, but the structure and material of the wiring pad are not specifically limited provided that electric power can be led out from the terminal block 1. In addition, in the embodiment shown in FIG. 1, the plurality of wiring pads 2 are configured on a side of the housing 5 in the width direction of the housing 5, but the configuration position of the wiring pads in the housing is not limited thereto.

The power output terminal and the power output terminal group will be explained below.

As shown in FIG. 1 and FIG. 2, on a side of the housing 5 opposite to the side where the wiring pads are located, a plurality of power output terminals 31 are provided in a manner of being partially exposed outside the housing. The power output terminals 31 are respectively electrically connected to the wiring pads 2. Each power output terminal 31 includes, for example, a cable electrically connected to the wiring pad 2 to receive power supply, and a socket connected to an end of the cable for plug connection. The length of the cable is not specifically limited in this embodiment, and the cables of respective power output terminals 31 may have the same length or a different length.

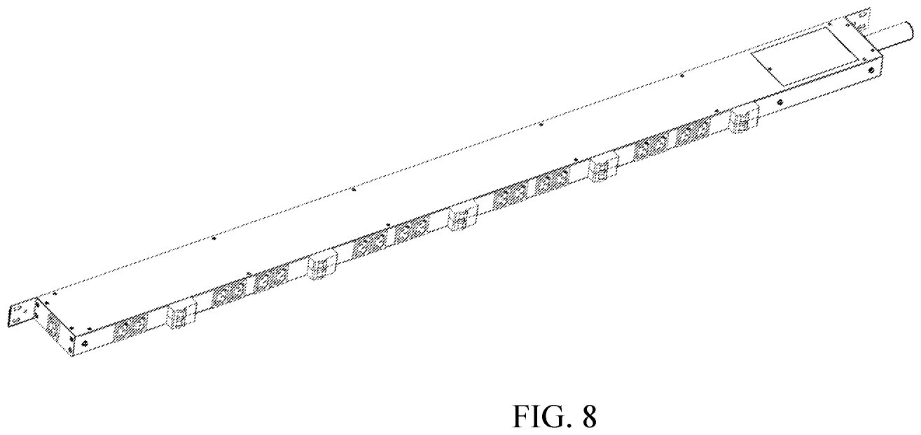

As shown in FIG. 1 and FIG. 2, for each power output terminal 31 provided on the housing 5, part of the cable and the socket may be exposed outside the housing. The power output terminals 31 are each configured in such a way that part of the cable and the socket are exposed outside the housing, the size of the housing 5 can be significantly reduced, or the number of the power output terminals 31 can be increased while the size of the housing is relatively fixed, to meet electricity needs of more electronic devices. However, the exposed part of the power output terminal 31 is not limited to the above form, and it is possible to expose only the socket (e.g., only a surface of the socket with insertion holes) outside the housing as shown in FIG. 8.

The power output terminals 31 may fall into a plurality of power output terminal groups 3. Each power output terminal group 3 may be composed of at least one power output terminal 31. It should be understood that the number of the power output terminal 31 included in each power output terminal group 3 is not limited in this embodiment, it may be two, three, four or more, and may be specifically set by those skilled in the art according to application scenarios. In addition, the respective power output terminal groups 3 are not necessarily composed of the same number of the power output terminal 31, and the number of the power output terminal 31 in some power output terminal groups 3 may be changed.

As shown in FIG. 1, FIG. 2 and FIG. 8, the plurality of power output terminal groups 3 are arranged along the length direction (first direction) of the power distribution unit, run through one side wall (first side wall 51) of the housing 5 extending along the first direction, and are partially exposed outside the housing.

The plurality of switch mechanisms 4 are provided corresponding to the respective power output terminal groups 3. A switch mechanism 4 controls electrical connection or electrical disconnection between a corresponding power output terminal group 3 and a corresponding wiring pad 2, thus achieving independent control and independent protection of each power output terminal group 3. In this embodiment, one switch mechanism 4 is provided corresponding to one power output terminal group 3.

By means of such an above-mentioned structure that a switch mechanism 4 is provided corresponding to a power output terminal group composed of a plurality of (e.g., two) power output terminals 31 and each switch mechanism 4 controls the corresponding power output terminal group 3, group control of multiple sockets in the power distribution unit can be achieved, various use requirements can be met, and the use flexibility is improved.

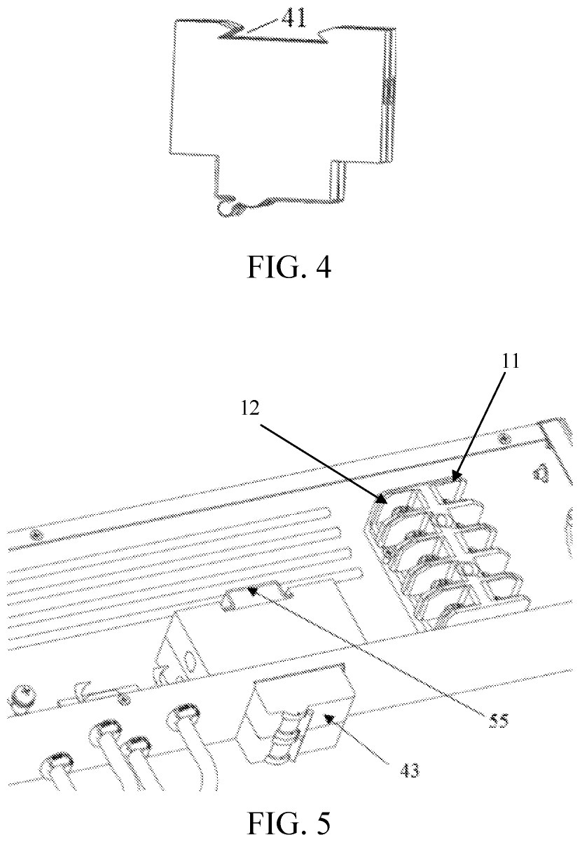

As shown in FIG. 1, FIG. 2 and FIG. 4, each switch mechanism 4 protrudes on a side wall (e.g., a first side wall 51) of the housing 5 that is provided with the power output terminals 31 in such a way that at least a switch lever 43 (described later) of the switch mechanism 4 is exposed outside the housing 5. In an embodiment, the switch mechanisms 4 are each configured at a position adjacent to a corresponding power output terminal group 3, and are arranged along the first direction. The respective switch mechanisms 4 may alternatively be overlapped in the thickness direction (second direction) of the power distribution unit. For example, every two switch mechanisms 4 overlap in the second direction to form an overlapping body of switch mechanisms, and the overlapping body is arranged in the vicinity of a corresponding power output terminal group 3 along the first direction. The number of switch mechanisms 4 overlapped in the second direction is not specifically limited in this embodiment, it may be two, three or more, and may be specifically set according to user requirements, a mounting space of the power distribution unit, etc.

In some embodiments of the present disclosure, at least two power output units may be formed from a plurality of power output terminal groups. For example, when a power output terminal group is composed of two power output terminals 31, every two power output terminal groups may form one power output unit. A plurality of power output units are arranged on the first side wall 51 of the housing along the first direction, and the respective power output units are provided spaced apart from each other. As an example, the respective power output units and the switch mechanisms 4 or the overlapping bodies of switch mechanisms are alternately provided along the first direction.

By means of the aforementioned arrangement of the switch mechanisms 4 and the power output terminal groups 3, the space of the power distribution unit can be fully utilized, and the flexibility of power distribution and control can be improved without increasing the mounting space of the power distribution unit. Moreover, compared with a conventional power distribution unit in which all output terminals are controlled by a main switch, each power output terminal 31 in this embodiment can have higher output power, thereby increasing the overall output power of the power distribution unit. In addition, the number of the power output terminal 31 may be increased to meet device requirements.

For example, when the power distribution unit is applied to a mining machine, as shown in FIG. 1, FIG. 2 and FIG. 8, each power output terminal group 3 may include four power output terminals 31, and the four power output terminals 31 are grouped in pairs. Two switch mechanisms 4 are overlapped in the second direction. One group of power output terminals 31 (that is, one power output terminal group) may be controlled by one of the overlapped switch mechanisms 4, and the other group of power output terminals 31 (that is, the other power output terminal group) may be controlled by the other one of the overlapped switch mechanisms 4. That is, each switch mechanism 4 controls two power output terminals 31, and when the switch mechanism 4 controls cables of the corresponding power output terminals 31 to be electrically connected to the corresponding wiring pads 2, the mining machine connected with the two cables is started.

By means of the aforementioned arrangement, the independent control of an external power consuming device by the switch mechanism 4 can be ensured, and the operation complexity caused by too many switch mechanisms 4 can also be reduced.

The structure of the switch mechanism 4 will be described below.

In an embodiment, as shown in FIG. 3 and FIG. 4, the switch mechanism 4 includes a switch body and a switch lever 43 provided at an end of the switch body. The switch body is provided with a special-shaped hole 42 for a cable to pass through, and the special-shaped hole 42 has a non-circular inner peripheral surface, so that the cable can be allowed to pass through but the movement (such as rotation and jumping) of the cable can be restricted. The cable can be fixed more firmly by means of the special-shaped hole 42, and it is not easy to move, thus preventing an energizing failure caused by the movement of the cable. The switch lever 43 is provided for a user to perform a disconnection or connection operation, and thus the user can conveniently control the power output of corresponding power output terminals 31, and the operation is simple.

In addition, as shown in FIG. 3 and FIG. 5, the switch mechanism 4 further includes a fixing groove 41 for mounting the switch mechanism. The fixing groove 41 is provided, for example, at the switch body at a position opposite to the switch lever 43. By means of fitting (e.g., snap-fit) between the fixing groove 41 and a fixed guide rail 55 provided in the housing 5 of the power distribution unit, the switch mechanism 4 can be easily fixed to the housing 5. As an example, the fixed guide rail 55 is mounted, for example, to a bottom wall of the housing 5, and the fixed guide rail 55 includes an upright wall which is upright (extending in the second direction) relative to the bottom wall in a mounted state. The upright wall (e.g., two ends of the upright wall) can be snap-fitted with the fixing groove 41 of the switch mechanism 4.

When a switch mechanism 4 is overlapped with another switch mechanism 4 in the second direction, the two switch mechanisms 4 in the overlapped state both fit with the fixed guide rail 55. In this way, each switch mechanism 4 can be easily mounted in a simple and mounting space-saving manner, without the need to additionally provide a structure or process for aligning the overlapped switch mechanisms 4.

In addition, the height of the fixed guide rail 55 (length dimension in the second direction) is not specifically limited, provided that the fixed guide rail can be snap-fitted with each of the overlapped switch mechanisms 4. However, from the perspective of suppressing the thickness of the power distribution unit, it is preferable that the height of the fixed guide rail 55 is not greater than the total height of the switch mechanism 4 snap-fitted with the fixed guide rail.

As an example, as shown in FIG. 4, the fixing groove 41 may be a dovetail groove. Through the mutual fitting between the dovetail groove and the fixed guide rail 55, the switch mechanism 4 and the fixed guide rail 55 can be snap-fitted with each other more stably and firmly, and it is not easy to shake.

As shown in FIG. 2, the housing 5 has a first side wall 51 and a second side wall 52 that extend in the first direction; a first end wall 53 and a second end wall 54 that are connected to two ends of the two side walls 51 and 52 in the first direction; and a top wall and a bottom wall that are opposite to each other and cover, in the second direction, a space enclosed by the first side wall 51, the second side wall 52, the first end wall 53 and the second end wall 54.

In an embodiment, an input incoming mechanism 6 is provided at an end of the housing 5 in the first direction, for example, at the first end wall 53.

In an embodiment, the input incoming mechanism 6 is electrically connected to the input terminal 11 of the terminal block 1, and the lead-out terminal 12 of the terminal block 1 is connected to each wiring pad 2; and the terminal block 1 is located inside the housing 5 at a position close to the first end wall 53. This can reduce the length of a power transmission line, and make rational use of the internal space of the housing.

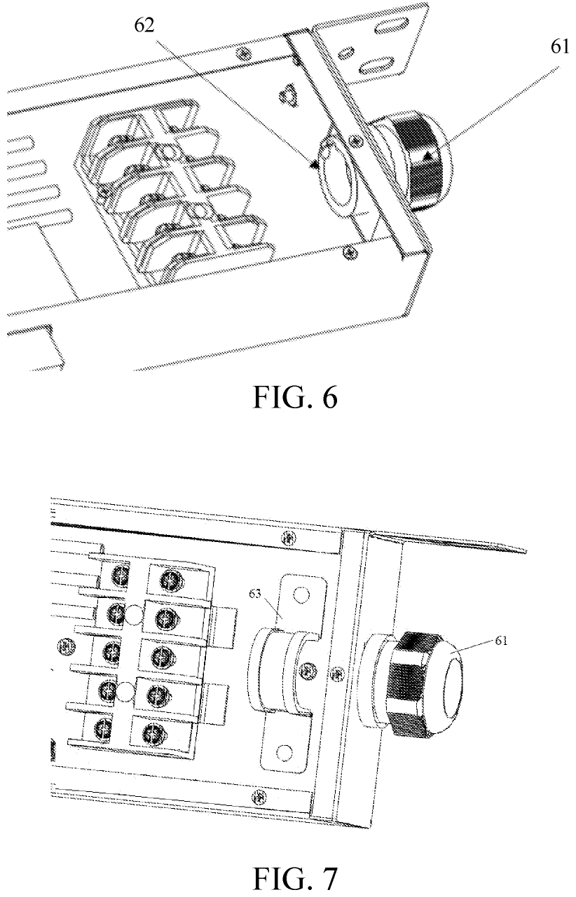

As an example, referring to FIG. 6, the input incoming mechanism 6 includes: a first hub ring 61 and a second hub ring 62.

In an embodiment, the first hub ring 61 is provided on a side of the first end wall 53 outside the housing 5; and the second hub ring 62 is provided on a side of the first end wall 53 inside the housing 5. The first hub ring 61 is provided with a mounting groove in a surrounding manner, and the first end wall 53 of the housing 5 is provided with a through hole for a cable to pass through. In this way, by means of communication between the mounting groove and the through hole, the first hub ring 61 is in communication with and connected to the second hub ring 62.

An annular structure is adopted for the input incoming mechanism 6, which can adapt to a larger-volume incoming cable and better meet the requirements of a high-power server. Inner diameter dimensions of the first hub ring 61 and the second hub ring 62 are not specifically limited in this embodiment, and may be determined according to required power of a current power consuming device or the size of the housing, to meet the requirements of different devices.

As an example, as shown in FIG. 7, the input incoming mechanism 6 of this embodiment may further include a locking mechanism 63. The locking mechanism 63 is configured to fix an external incoming cable into the housing 5. As an example, the locking mechanism is, for example, in an inverted U shape, the locking mechanism covers the external incoming cable, and flanges at two ends of an opening of the inverted U are fixed to the bottom wall of the housing 5, so as to fix the external incoming cable. In addition, at least one rib (not shown) may be provided on the side of the locking mechanism 63 that is in contact with the cable, and the rib abuts against an outer surface of the cable in a mounted state, so as to clamp and fix the cable.

An annular structure is adopted for the input incoming mechanism 6 to allow the cable to pass through, which can adapt to a larger-volume incoming cable and increase input power. The locking mechanism is provided inside the housing to fix the external incoming cable, and can reliably fix the incoming cable even for a large-volume incoming cable.

In addition, as an example, as shown in FIG. 1, FIG. 2 and FIG. 8, a socket may also be provided at an end of the housing 5 away from the input incoming mechanism 6, for example, on the second end wall 54, thereby further increasing the number of power outputs, and thus further improving the space utilization of the power distribution unit without occupying the position of the power output terminal group 3. In addition, different types of power receiving devices can be arranged on different surfaces, to facilitate management without the need for additional provision of a socket, a power strip, etc. It should be understood that the output terminal provided on the second end wall 54 may include not only a socket, or may include a cable and a socket. Similarly, the output terminal arranged on the second end wall 54 may be controlled by a switch mechanism 4 adjacent thereto, or by the main switch of the power distribution unit, or by another switch mechanism.

As an example, the power distribution unit further includes a mounting bracket such as a mounting frame for mounting a server. As an example, as shown in FIG. 1, FIG. 2 and FIG. 8, the power distribution unit includes a first mounting bracket 7 and a second mounting bracket 8.

As an example, the first mounting bracket 7 is provided outside the first end wall 53 of the housing 5 and is connected to the first end wall 53 of the housing 5, and the second mounting bracket 8 is provided outside the second end wall 54 of the housing 5 and is connected to the second end wall 54 of the housing 5. The first mounting bracket 7 and the second mounting bracket 8 each are provided with a mounting through-hole. For example, the first mounting bracket 7 and the second mounting bracket 8 may be securely mounted to a server mounting frame, a server rack, or the like by causing screws, etc. to pass through the mounting through-holes. As an example, the mounting through-hole includes an elongated hole, and thus the mounting position of the power distribution unit can be conveniently adjusted.

The power distribution unit with the above structure may be mounted to a rack. As an example, the rack may include a plurality of columns and a plurality of laminates fixed between the columns. The columns may be vertically provided, and the laminates extend along a plane perpendicular to the columns. Edges of the laminates may be fixed to the plurality of columns, and various power consuming devices, such as a server, may be placed above the laminates. The power distribution unit as described above is mounted to the laminate in such a way that the length direction of the power distribution unit is consistent with an extension direction of the laminate, and for example, is mounted to a side surface of the laminate. Therefore, power can be distributed to the power consuming devices such as the server placed on the laminates, and whether each server is energized can be independently controlled.

According to the embodiments described above, an embodiment of the present disclosure provides a power distribution unit. The power distribution unit includes: a terminal block 1 having an input terminal 11 for power supply and a lead-out terminal 12 for power supply; at least one wiring pad 2 respectively electrically connected to the lead-out terminal 12; a plurality of power output terminal groups 3, each power output terminal group 3 being composed of at least one power output terminal 31, and each power output terminal 31 being electrically connected to a respective wiring pad 2; and a plurality of switch mechanisms 4 provided in such a way that a switch mechanism 4 is correspondingly provided for a power output terminal group 3. The switch mechanism 4 causes a corresponding power output terminal group 3 to be electrically connected to or electrically disconnected from the corresponding wiring pad 2.

As an example, in the power distribution unit as described above, one switch mechanism 4 is correspondingly provided for one power output terminal group 3, and each power output terminal group 3 is composed of two power output terminals 31.

As an example, in the power distribution unit as described above, the plurality of power output terminal groups 3 form at least two power output units, and the respective power output units are provided spaced apart from each other.

As an example, in the power distribution unit as described above, the power output units are arranged along a first direction, and the switch mechanisms 4 are each provided at a position adjacent to a corresponding power output unit, and are arranged along the first direction.

As an example, in the power distribution unit as described above, when a power output unit is composed of a plurality of power output terminal groups 3, a plurality of switch mechanisms 4 corresponding to the power output unit are arranged along a second direction perpendicular to the first direction.

As an example, in the power distribution unit as described above, the switch mechanism 4 includes a fixing groove 41 for mounting the switch mechanism, and the fixing groove 41 is fitted with a fixed guide rail 55 provided at a housing 5 of the power distribution unit.

As an example, the fixing groove 41 is a dovetail groove.

As an example, in the power distribution unit as described above, the switch mechanism 4 includes a special-shaped hole 42 for allowing a cable to pass through and fixing the cable and a switch lever 43 for operation; and the power output terminal 31 includes a socket.

As an example, in the power distribution unit as described above, a plurality of wiring pads 2 are provided, and the respective wiring pads 2 are connected independently of each other to the terminal block 1.

As an example, the power distribution unit as described above further includes a housing 5. The housing 5 has: a first side wall 51 and a second side wall 52 extending along the first direction and opposite to each other; a first end wall 53 and a second end wall 54 which are provided at two ends of the first side wall 51 and the second side wall 52 in the first direction; and a top wall and a bottom wall that are opposite to each other and cover a space enclosed by the first side wall 51, the second side wall 52, the first end wall 53 and the second end wall 54. At least part of the switch mechanism 4 and at least part of the power output terminal 31 are exposed at the first side wall 51.

As an example, in the power distribution unit as described above, the switch lever 43 of the switch mechanism 4 that is for operation, a cable of the power output terminal 31, and a socket connected to an end of the cable are exposed at the first side wall 51; and/or the switch lever 43 of the switch mechanism 4 that is for operation and the socket of the power output terminal 31 are exposed at the first side wall 51.

As an example, in the power distribution unit as described above, an input incoming mechanism 6 is provided at the first end wall 51, the input incoming mechanism 6 is electrically connected to the input terminal 11 of the terminal block 1, and the terminal block 1 is located inside the housing 5 at a position close to the first end wall 53.

As an example, in the power distribution unit as described above, the input incoming mechanism 6 includes: a first hub ring 61 provided on a side of the first end wall 53 outside the housing; and a second hub ring 62 provided on a side of the first end wall 53 inside the housing. The first hub ring 61 is provided with a mounting groove in a surrounding manner, the first end wall 53 of the housing 5 is provided with a through hole for a cable to pass through, and the mounting groove is in communication with the through hole and is connected to the second hub ring 61.

As an example, in the power distribution unit as described above, the input incoming mechanism 6 further includes: a locking mechanism 63 mounted to the bottom wall. The locking mechanism and the bottom wall form a routing channel, and the cable is fixed inside the routing channel.

As an example, in the power distribution unit as described above, at least one fixed guide rail 55 is provided in the housing, the fixed guide rail 55 is mounted to the bottom wall, the fixed guide rail 55 includes an upright wall which is upright relative to the bottom wall in a mounted state, and the upright wall can be snap-fitted with the fixing groove 41 provided in the switch mechanism 4.

As an example, in the power distribution unit as described above, the second end wall 54 is provided with a socket.

As an example, the power distribution unit as described above further includes: a first mounting bracket 7 provided outside the first end wall 53 and connected to the first end wall 53, the first mounting bracket 7 being provided with a mounting through-hole; and a second mounting bracket 8 provided outside the second end wall 54 and connected to the second end wall 54, the second mounting bracket 8 being provided with a mounting through-hole.

An embodiment of the present disclosure further provides a rack system, including: a rack and a power distribution unit as described above. The rack includes a plurality of parallel laminates provided spaced apart from each other, and the power distribution unit is fixed to a side surface of a laminate.

In the embodiment of the present disclosure, the fully utilization of an internal space and a surface of the power distribution unit is achieved by reasonably arranging the respective power output terminals and the respective switch mechanisms. Moreover, by corresponding arrangement of a switch mechanism for one group of power output terminals, and independent control of the corresponding power output terminal group by the switch mechanism, the independent control of the power output terminals in groups is achieved, the use flexibility is improved, and output power of each power output terminal can also be increased. In addition, the switch mechanism can be easily and reliably fixed relative to the housing by means of the fitting between the fixing groove and the fixed guide rail, thereby simplifying the internal structure of the power distribution unit and improving the mounting efficiency. Furthermore, with the provision of the special-shaped hole in the switch mechanism, the movement of the cable can be restricted. With the provision of two hub rings and the locking mechanism with a rib, it is possible to adapt to a larger-volume incoming cable, increase the input power of the power distribution unit, and reliably fix the incoming cables.

The implementations of the embodiments of the present disclosure are described above by way of illustration. Those skilled in the art should understand that application scenarios of the embodiments of the present disclosure are not limited to a server rack, a machine room and other scenarios, but the embodiments may also be applied to a household power strip, and the like.

It should be understood that the embodiments of the present disclosure are not limited to the precise structures described above and shown in the accompanying drawings, and various modifications and changes may be made without departing from the scope thereof. The scope of the embodiments of the present disclosure is defined merely by the appended claims.

What is claimed is:

1. A power distribution unit, comprising:
a terminal block having an input terminal for power supply and a lead-out terminal for power supply;
at least one wiring pad electrically connected to the lead-out terminal;
a plurality of power output terminal groups, each power output terminal group being composed of at least one power output terminal, and each power output terminal being electrically connected to a respective wiring pad; and
a plurality of switch mechanisms provided in such a way that a switch mechanism is correspondingly provided for a power output terminal group, wherein the switch mechanism causes the corresponding power output terminal group to be electrically connected to or electrically disconnected from the corresponding wiring pad.

2. The power distribution unit according to claim 1, wherein,
one switch mechanism is correspondingly provided for one power output terminal group,
each power output terminal group is composed of two power output terminals.

3. The power distribution unit according to claim 1, wherein,
the plurality of power output terminal groups form at least two power output units, and the respective power output units are provided spaced apart from each other.

4. The power distribution unit according to claim 3, wherein,
the power output units are arranged along a first direction,
the switch mechanisms are each configured at a position adjacent to a corresponding power output unit, and are arranged along the first direction.

5. The power distribution unit according to claim 4, wherein,
when a power output unit is composed of a plurality of power output terminal groups, a plurality of switch mechanisms corresponding to the power output unit are arranged along a second direction perpendicular to the first direction.

6. The power distribution unit according to claim 1, wherein the switch mechanism comprises a fixing groove for mounting the switch mechanism, and the fixing groove is fitted with a fixed guide rail provided at a housing of the power distribution unit.

7. The power distribution unit according to claim 6, wherein the fixing groove is a dovetail groove.

8. The power distribution unit according to claim 6, wherein,
the switch mechanism comprises a special-shaped hole for allowing a cable to pass through and fixing the cable and a switch lever for operation;
the power output terminal comprises a socket.

9. The power distribution unit according to claim 1, wherein,
a plurality of wiring pads are provided, and the respective wiring pads are connected independently of each other to the terminal block.

10. The power distribution unit according to claim 1, further comprising a housing, wherein the housing has:
a first side wall and a second side wall extending along a first direction and opposite to each other;
a first end wall and a second end wall which are provided at two ends of the first side wall and the second side wall in the first direction; and
a top wall and a bottom wall which are opposite to each other and cover a space enclosed by the first side wall, the second side wall, the first end wall and the second end wall;
wherein at least part of the switch mechanism and at least part of the power output terminal are exposed at the first side wall.

11. The power distribution unit according to claim 10, wherein,
a switch lever of the switch mechanism that is for operation, a cable of the power output terminal, and a socket connected to an end of the cable are exposed at the first side wall; and
the switch lever of the switch mechanism that is for operation and the socket of the power output terminal are exposed at the first side wall.

12. The power distribution unit according to claim 10, wherein,
a switch lever of the switch mechanism that is for operation, a cable of the power output terminal, and a socket connected to an end of the cable are exposed at the first side wall.

13. The power distribution unit according to claim 10, wherein,
a switch lever of the switch mechanism that is for operation and a socket of the power output terminal are exposed at the first side wall.

14. The power distribution unit according to claim 10, wherein
an input incoming mechanism is provided at the first end wall, the input incoming mechanism is electrically connected to the input terminal of the terminal block, and the terminal block is located inside the housing at a position close to the first end wall.

15. The power distribution unit according to claim 14, wherein the input incoming mechanism comprises:
a first hub ring provided on a side of the first end wall outside the housing; and
a second hub ring provided on a side of the first end wall inside the housing,
wherein the first hub ring is provided with a mounting groove in a surrounding manner, the first end wall of the housing is provided with a through hole for a cable to pass through, and the mounting groove is in communication with the through hole and is connected to the second hub ring.

16. The power distribution unit according to claim 15, wherein the input incoming mechanism further comprises:
a locking mechanism mounted to the bottom wall, wherein the locking mechanism and the bottom wall form a routing channel, and the cable is fixed inside the routing channel.

17. The power distribution unit according to claim 14, wherein
at least one fixed guide rail is provided in the housing, the fixed guide rail is mounted to the bottom wall, the fixed guide rail comprises an upright wall which is upright relative to the bottom wall in a mounted state, and the upright wall is capable of being snap-fitted with a fixing groove provided in the switch mechanism.

18. The power distribution unit according to claim 10, wherein the second end wall is provided with a socket.

19. The power distribution unit according to claim 10, further comprising:
a first mounting bracket provided outside the first end wall and connected to the first end wall, the first mounting bracket being provided with a mounting through-hole; and
a second mounting bracket provided outside the second end wall and connected to the second end wall, the second mounting bracket being provided with a mounting through-hole.

20. A rack system, comprising: a rack and a power distribution unit, wherein the rack comprises a plurality of parallel laminates provided spaced apart from each other, and the power distribution unit is fixed to a side surface of a laminate;
wherein the power distribution unit comprises:
a terminal block having an input terminal for power supply and a lead-out terminal for power supply;
at least one wiring pad electrically connected to the lead-out terminal;
a plurality of power output terminal groups, each power output terminal group being composed of at least one power output terminal, and each power output terminal being electrically connected to a respective wiring pad; and
a plurality of switch mechanisms provided in such a way that a switch mechanism is correspondingly provided for a power output terminal group, wherein the switch mechanism causes the corresponding power output terminal group to be electrically connected to or electrically disconnected from the corresponding wiring pad.
